(19) United States
(12) Patent Application Publication
(10) Pub. No.: US 2017/0291172 A1
(43) Pub. Date: Oct. 12, 2017

(54) TUNABLE, SHEATHLESS, AND THREE DIMENSIONAL SINGLE-STREAM CELL FOCUSING AND SORTING IN HIGH SPEED FLOWS

(71) Applicant: The Regents of the University of California, Oakland, CA (US)

(72) Inventors: YU-CHUN KUNG, Los Angeles, CA (US); PEI-YU E. CHIOU, Los Angeles, CA (US)

(21) Appl. No.: 15/484,964

(22) Filed: Apr. 11, 2017

Related U.S. Application Data
(60) Provisional application No. 62/321,133, filed on Apr. 11, 2016.

(51) Int. Cl. B01L 3/00; G01N 27/447; G01N 1/10; F04B 43/04; F16K 99/00

(52) U.S. Cl. CPC B01L 3/50273; F04B 43/043; F16K 99/0001; F16K 99/0015; G01N 1/10; G01N 27/44791; B81B 1/00

(57) ABSTRACT

In various embodiments methods and devices are provided for focusing and/or sorting particles and/or cells in a microfluidic channel. In certain embodiments the device comprises a microfluidic channel comprising a plurality of electrodes disposed to provide dielectrophoretic (DEP) forces that are perpendicular to hydrodynamic flows along the channel; wherein said device is configured to apply voltages to said electrodes to provide an electric field minimum that is not centered in said microfluidic channel.

### CROSS-REFERENCE TO RELATED APPLICATIONS

This application claims priority to and benefit of U.S. Ser. No. 62/321,133, filed on Apr. 11, 2016, which is incorporated herein by reference in its entirety for all purposes.

### STATEMENT OF GOVERNMENTAL SUPPORT

This invention was made with government support under Grant Nos. DBI 1256178 and ECCS1232279 awarded by the National Science Foundation. The Government has certain rights in this invention.

### BACKGROUND

Accurate and high throughput cell sorting technologies are critical for applications in molecular and cellular biology, biotechnology, and medicine (Shields, et al. (2015) Lab Chip, 15: 1230-1249). Biological, chemical, or medical processes involving complex fluids with embedded particles (e.g., blood) often require preparative separation of particles, cells, or even molecules that are needed for subsequent procedures. In conventional macroscale separation processes, centrifugation and membrane filtration approaches have been commonly used for decades, whereas more sophisticated methods such as fluorescence-activated cell sorting (FACS) and magnetically activated cell separation (MACS) were rapidly established as the standard methods for high quality cell and particle separation. While conventional methods can provide highly efficient label-based sorting in short timescales, advances in microfluidics have enabled miniature devices not only offering similar capabilities (Chen et al. (2013) Analyst, 138: 7308-7315; Fan et al. (2013) Biomicrofluidics, 7: 044121), but also unprecedented label-free sorting functions by exploiting a variety of physical parameters as biomarkers, such as cell size, deformability, compressibility, shape, density, size, surface properties, electrical polarizability, magnetic susceptibility and refractive index. Among these, cell size is the most straight-forward feature and sorting based on size can be easily accessible through microfiltration (Mohamed et al. (2004) IEEE Transactions on Nanobioscience, 3: 251-256), pinched flow fractionation (Yamada et al. (2004) Analyt. Chem. 76: 5465-5471), inertial microfluidics (Amini et al. (2014) Lab Chip, 14: 2739-2761), acoustophoresis (Petersson et al. (2007) Analyt. Chem. 79: 5117-5123), and dielectrophoresis (Kim et al. (2007) Proc. Natl. Acad. Sci. USA, 104: 20708-20712). However, a high throughput and reliable approach is still lacking for high purity sorting of particles with small size difference.

Particles in different streamlines in a microfluidic channel flow at different speeds due to the parabolic flow velocity distribution resulting from the zero-slip boundary conditions and viscous fluid environment. Focusing randomly distributed particles into a narrow stream in a continuous flow allows all particles to flow at the same speed and in the same cross-section location. This function is critical for applications that need accurate synchronization and coordination of particles in both space and time domains, for example, flow cytometer, one of the most efficient and effective approaches for single cell analysis. One of the core features of a flow cytometer is the ability to three-dimensionally focus cells and particles into a single stream. This allows all particles and cells to travel at an identical speed through an optical detection zone such that all particles receive the same illumination intensity and time for reliable and consistent optical detection (Cram (2002) Meth. Cell. Sci. 24(1): 1-9). Fluorescence activated cell sorter (FACS) is a special type of flow cytometer that adds a downstream sorting function to select target particles detected in the upstream. Tight particle focusing is extremely important to synchronize the detection and switching event. Without particle focusing, particle flow speed varies and the arrival time of particles into the switching zone is difficult to predict, which results in failure of sorting out target particles or cells. For many other particle sorting techniques that are based on magnetic forces, dielectrophoresis, acoustics, inertial forces, tight particle focusing is also important to provide particles and cells of different properties a common reference in space for high efficiency and high purity sorting.

Particle focusing can be achieved by many prior approaches. Traditionally, sheath fluid is used to sandwich the sample fluid in a co-flow manner. The laminar flow nature in microfluidics allows tight focusing to be achieved by using a large sheath-to-sample fluid ratio. However, serious dilution of sample is a potential concern for many applications. Tuning particle focusing location can be realized by changing the input sheath flows, yet it takes some time before the new equilibrium focusing location becomes stabilized. To eliminate the need of sheath flows for focusing, some other approaches have been developed.

Inertia effects of particles flowing in high-speed flows have recently been found significant in microfluidic channels. Particles can be focused into few equilibrium streams where hydrodynamic forces on particles resulting from flow velocity gradient and wall effects are equal. Single stream microparticle focusing can also be achieved by using secondary flows induced by periodic structures (Chen et al. (2014) Small 10(9): 1746-1751; Chung et al. (2013) Small, 9(5): 685-690; Chung et al. (2014) Lab Chip, 13(15): 2942-2949; Lee et al. (2009) Lab Chip, 9(21): 3155-3160). Some limitations of inertial focusing include size-dependent focusing location, insensitive to small sized particles, focusing stability after passing through focusing structures, unprecise focusing, and the need of high-speed flows. Tuning focusing stream location in real-time might be challenge since the equilibrium positions are dependent upon channel geometry and flow speed.

Acoustic focusing is another broadly applied mechanism. By forming standing acoustic waves in microfluidic channels, either through bulk acoustic waves (BAW) (Antfolk et al. (2014) Lab Chip, 14(15): 2791-2799; Grenvall et al. (2014) Lab Chip, 14(24): 4629-4637; Chen et al. (2014) Lab Chip, 14(5): 916-923; Shi et al. (2008) Lab Chip, 8(2): 221-223; Shi, et al. (2011) Lab Chip, 11(14): 2319-2324) or surface acoustic waves (SAW) (Chen et al. (2014) Lab Chip, 14(5): 916-923; Shi et al. (2008) Lab Chip, 8(2): 221-223; Shi, et al. (2011) Lab Chip, 11(14): 2319-2324), particles and cells can be focused to nodal points. Acoustic focusing approaches can provide tunable focusing functions by either adding an additional echo channel in the BAW cases (Fong et al. (2014) Analyst, 139(5): 1192-1200; Jung et al. (2015) Lab Chip, 15(4): 1000-1003) or using chirped inter-digital transducers (IDT) as in the SAW-based approaches (Ding et al. (2012) Lab Chip, 12(21): 4228-4231; Li et al. (2013) Analyt. Chem., 85(11): 5468-5474). However, such tuning is currently limited to one dimension across the channel, unprecise focusing, and multiple focusing positions across the channel cross section.

Dielectrophoretic forces have also been utilized to provide focusing functions in microfluidics. This electrical based mechanism provides a great tuning flexibility since the applied voltages can be continuously and easily adjusted in real-time. However, limited DEP forces, typically in the orders of tens of pN, prevent most current DEP devices from providing tight focusing functions in high-speed flows (Haandbæk et al. (2014) Lab Chip, 14(17): 3313-3324; Holmes et al. (2006) Biosensors and Bioelectronics, 21(8): 1621-1630; Morgan et al. (2003) IEEE Proc.-Nanobiotechnol, 150(2): 76-81), which also limit their throughputs. Furthermore, DEP devices usually require the manipulated particles and cells to be suspended in isotonic buffers with low ionic strength to increase DEP forces and responsibility of cells. Such low ionic buffers, different from regular physiological buffers, may impact cells' physiological conditions and viability.

### SUMMARY

Various embodiments contemplated herein may include, but need not be limited to, one or more of the following:

### Embodiment 1

A device for focusing cells, viruses, particles, molecules or molecular complexes in a microfluidic channel, said device comprising:
a microfluidic channel comprising a plurality of electrodes disposed on surfaces of said channel to provide three-dimensional spatially tunable tunnel electric field minimum for dielectrophoretic (DEP) forces that are perpendicular to hydrodynamic flows along the channel; and
a fluid within said channel providing said hydrodynamic flow along said channel;
wherein said device is configured to apply voltages to said electrodes to provide an spatially adjustable electric field minimum or electric field pattern that is programmable by the voltage combinations on each electrodes.

### Embodiment 2

The device of embodiment 1, wherein said device comprises:
a microfluidic channel comprising a plurality of electrodes disposed to provide dielectrophoretic (DEP) forces that are perpendicular to hydrodynamic flows along the channel; and
wherein said device is configured to apply voltages to said electrodes to provide an electric field minimum that is not centered in said microfluidic channel.

### Embodiment 3

The device according to any one of embodiments 1-2, wherein said device is configured to apply voltages independently to each of said electrodes.

### Embodiment 4

The device according to any one of embodiments 1-3, wherein said device comprises two pairs of electrodes disposed parallel to each other around the microfluidic channel.

### Embodiment 5

The device according to any one of embodiments 1-4, wherein said plurality of electrodes comprises electrodes disposed along each side of said microfluidic channel at or near the top of said channel and electrodes disposed along each side of said microfluidic channel at or near the bottom of said channel.

### Embodiment 6

The device according to any one of embodiments 1-4, wherein said plurality of electrodes comprises electrodes disposed along the midline of each side of said microfluidic channel and along the midline of the top and bottom of said channel.

### Embodiment 7

The device according to any one of embodiments 1-6, said device applies an ac voltage to said electrodes.

### Embodiment 8

The device of embodiment 7, wherein said ac voltage applied to said electrodes is independently at a frequency ranging from about 0 Hz, or from about 1 Hz, or from about 100 Hz, or from about 1 kHz, or from about 10 kHz, or from about 50 kHz, or from about 100 kHz, or from about 500 kHz, up to about 5 MHz, or up to about 10 MHz, or up to about 15 MHz, or up to about 20 MHz, or up to about 50 MHz, or up to about 100 MHz, or up to about 500 MHz, or ranging from about 10 kHz, or from about 50 kHz, or from about 100 kHz, or from about 500 kHz, up to about 5 MHz, or up to about 10 MHz, or up to about 15 MHz, or up to about 20 MHz.

### Embodiment 9

The device according to any one of embodiments 7-8, wherein said voltage applied to said electrodes independently ranges from about close to 0V, or from about 0.001 mV, or from about 0.01 mV, or from about 0.1 mV, or from about 1 mV, or from about 100 mV, or from about 500 mV, or from about 1V, or from about 5V, or from about 10V, up to about 500V, or up to about 100V, or up to about 80V, or up to about 50V, or up to about 40V, or up to maximum voltage above which a fluid in said channel will undergo electrolysis, or ranges from about 1V, or from about 5V, or from about 10V, up to about 100V, or up to about 80V, or up to about 50V, or up to about 40V.

### Embodiment 10

The device according to any one of embodiments 1-9, wherein said electrodes are configured to provide a field minimum at or near a lower or upper corner (diagonal region) of said channel.

### Embodiment 11

The device according to any one of embodiments 1-9, wherein said electrodes are configured to provide a field minimum at or near one side of said channel and/or at or near the top or bottom of said channel.

### Embodiment 12

The device according to any one of embodiments 1-11, wherein said microfluidic channel length is at least about 10 μm, or at least about 100 μm, or at least about 500 μm, or at least about 1 cm, or at least about 2 cm, or at least about 3 cm, or at least about 4 cm, or at least about 5 cm, or at least about 6 cm, or at least about 7 cm, or at least about 8 cm, or at least about 9 cm, or at least about 10 cm, or at least about 25 cm, or at least about 50 cm, or at least about 80 cm, or at least about 100 cm.

### Embodiment 13

The device of embodiment 12, wherein said channel is linear.

### Embodiment 14

The device of embodiment 12, wherein said channel is serpentine.

### Embodiment 15

The device of embodiment 14, wherein said channel is serpentine and has a length greater than a linear length of the substrate in which said channel is disposed.

### Embodiment 16

The device according to any one of embodiments 1-15, wherein the average depth of said microfluidic channel ranges from about 0.1 μm, or from about 0.5 μm, or from about 1 μm, or from about 10 μm, or from about 20 μm, or from about 30 μm, up to about 100 μm, or up to about 80 μm, or up to about 60 μm, or up to about 50 μm, or up to about 40 μm.

### Embodiment 17

The device according to any one of embodiments 1-16, wherein the average width of said microfluidic channel ranges from about 0.1 μm, or from about 0.5 μm, or from about 1 μm, or from about 10 μm, or from about 20 μm, or from about 30 μm, or from about 40 μm, or from about 50 μm, or from about 80 μm, or from about 100 μm up to about 500 μm, or up to about 400 μm, or up to about 300 μm, or up to about 200 μm, or up to about 400 μm, or up to about 500 μm, or up to about 1 mm.

### Embodiment 18

The device according to any one of embodiments 1-17, wherein said fluid has a conductivity that ranges from about 10⁻⁶ S/m, or from about 10⁻⁵ S/m, or from about 10⁻⁴ S/m, or from about 10⁻³ S/m, or from about 10⁻² S/m up to about 10 S/m, or up to about 5 S/m, or up to about 2 S/m, or up to about 1.5 S/m, or up to about 1 S/m.

### Embodiment 19

The device according to any one of embodiments 1-18, wherein said fluid comprises a physiological buffer.

### Embodiment 20

The device of embodiment 19, wherein said buffer comprises a mammalian ringer's solution.

### Embodiment 21

The device of embodiment 18, wherein said fluid comprises PBS.

### Embodiment 22

The device according to any one of embodiments 18-21, wherein the conductivity of said fluid is about 1 S/m.

### Embodiment 23

The device according to any one of embodiments 1-22, wherein said hydrodynamic flows are at a rate ranging up to about 10 m/s, or up to about 5 m/s, or up to about 1 m/s, or up to about 50 cm/s, or up to about 20 cm/s, or up to about 15 cm/s, or up to about 11 cm/s, or up to about 10 cm/s, or up to about 8 cm/s, or up to about 5 cm/s, or up to about 3 cm/s, or up to about 1 cm/s, or up to about 500 μm/s, or up to about 250 μm/s, or up to about 100 μm/s, or up to about 50 μm/s, or up to about 30 μm/s, or up to about 20 μm/s, or up to about 10 μm/s.

### Embodiment 24

The device according to any one of embodiments 1-23, wherein channel is fabricated from a material selected from the group consisting of silicon, a plastic, and an elastomeric material.

### Embodiment 25

The device of embodiment 24, wherein said elastomeric material is selected from the group consisting of polydimethylsiloxane (PDMS), polyolefin plastomers (POPs), perfluoropolyethylene (a-PFPE), polyurethane, polyimides, and cross-linked NOVOLAC® (phenol formaldehyde polymer) resin.

### Embodiment 26

The device of embodiment 24, wherein said channel is fabricated from PDMS.

### Embodiment 27

A method of focusing cells, organelles, viruses, particles, molecules or molecular complexes to an off-center location in a microchannel, said method comprising:

introducing said cells, organelles, viruses, particles, molecules or molecular complexes into a device according to any one of embodiments 1-26, wherein said electrodes provide an electric field minimum that is not centered in said microfluidic channel; and

flowing said cells, organelles, viruses, particles, molecules or molecular complexes along a length of the channel sufficient to permit said cells, organelles, viruses, particles, molecules or molecular complexes to focus in said channel at an off-center location wherein said off-center location is the location of an electric field minimum.

### Embodiment 28

The method of embodiment 27, wherein said flowing comprises flowing said cells or particles along at least about 100 μm, or at least about 500 μm, or at least about 1 cm, or at least about 2 cm, or at least about 3 cm, or at least about 4 cm, or at least about 5 cm, at least about 10 cm, or at least about 25 cm, or at least about 50 cm, or at least about 80 cm, or at least about 100 cm of said channel.

### Embodiment 29

The method according to any one of embodiments 27-28, wherein said flowing comprises flowing said cells or particle at a rate ranging up to about 10 m/s, or up to about 5 m/s, or up to about 3 m/s, or up to about 1 m/s, or up to about 50 cm/s, or up to about 20 cm/s, or up to about 15 cm/s, or up to about 11 cm/s, or up to about 10 cm/s, or up to about 8 cm/s, or up to about 5 cm/s, or up to about 3 cm/s, or up to about 1 cm/s, or up to about 500 μm/s, or up to about 250 μm/s, or up to about 100 μm/s, or up to about 50 μm/s, or up to about 25 μm/s, or up to about 10 μm/s.

### Embodiment 30

The method according to any one of embodiments 27-29. wherein said cells, viruses, particles, molecules or molecular complexes comprise a moiety selected from the group consisting of a particle, a biological molecule, a biological complex, an immune complex, a liposome, a protoplast, a platelet, a bacterium, a virus, and a prokaryotic cell, and a eukaryotic cell.

### Embodiment 31

The method according to any one of embodiments 27-30, wherein said cells, viruses, particles, molecules or molecular complexes comprise a particle.

### Embodiment 32

The method according to any one of embodiments 27-30, wherein said cells, viruses, particles, molecules or molecular complexes comprise a cell.

### Embodiment 33

The method of embodiment 32, wherein said cell comprises a prokaryotic cell.

### Embodiment 34

The method of embodiment 32, wherein said cell comprises a eukaryotic cell.

### Embodiment 35

The method of embodiment 34, wherein said cell comprises a mammalian cell.

### Embodiment 36

The method according to any one of embodiments 31-35, wherein said cell is in a physiological buffer.

### Embodiment 37

The method of embodiment 32, wherein said cell is in an isotonic buffer.

### Embodiment 38

A device for sorting cells, organelles, viruses, particles, molecules or molecular complexes, said device comprising:
a microfluidic channel comprising: a first region comprising a first plurality of electrodes disposed to provide dielectrophoretic (DEP) forces that are perpendicular to hydrodynamic flows along the first region of said channel; and
a second region downstream from said first region comprising a second plurality of electrodes disposed to provide dielectrophoretic (DEP) forces that are perpendicular to hydrodynamic flows along the second region of said channel;
a fluid within said channel providing said hydrodynamic flow along said channel; and
wherein said device is configured to apply voltages to first plurality of electrodes to provide an electric field minimum at a first location in the cross-section of said channel and to apply voltages to said second plurality of electrodes to provide an electric field minimum at a second location in the cross-section of said channel, where said first location and said second location are different locations in the cross-section of said channel.

### Embodiment 39

The device of embodiment 38, wherein said first location is at or near a wall of said channel and said second location is at or near the opposite wall of said channel.

### Embodiment 40

The device of embodiment 38, wherein said first location is at or near a corner of said channel and said second location is diagonally opposite at or near a corner of said channel.

### Embodiment 41

The device according to any one of embodiments 38-40, wherein the second region of said channel diverges into a plurality of channels whereby different size particle are diverted into different channels providing particle having different size or size distribution in each different channel of said plurality of channels.

### Embodiment 42

The device of embodiment 41, wherein said second region diverges into two different channels.

### Embodiment 43

The device of embodiment 41, wherein said second region diverges into 3, 4, 5, 6, 7, 8, 9, or 10 or more channels.

### Embodiment 44

The device according to any one of embodiments 38-43, wherein said device comprises a port or channel for introducing said cells, viruses, particles, molecules or molecular complexes into the first region of said channel.

### Embodiment 45

The device according to any one of embodiments 38-44, wherein said device comprises a port or channel for introducing a sheath flow into said microfluidic channel.

### Embodiment 46

The device according to any one of embodiments 38-45, wherein said first plurality of electrodes and said second plurality of electrodes independently each comprise two pairs of electrodes disposed parallel to each other around that region of the microfluidic channel.

### Embodiment 47

The device according to any one of embodiments 38-46, wherein said first plurality of electrodes and said second plurality of electrodes each comprises electrodes disposed along each side of said microfluidic channel at or near the top of said channel and electrodes disposed along each side of said microfluidic channel at or near the bottom of said channel.

### Embodiment 48

The device according to any one of embodiments 38-46, wherein said first plurality of electrodes and said second plurality of electrodes each comprises electrodes disposed along the midline of each side of said microfluidic channel and along the midline of the top and bottom of said channel.

### Embodiment 49

The device according to any one of embodiments 38-48, said device applies an ac voltage to first plurality of electrodes and to said second plurality electrodes.

### Embodiment 50

The device of embodiment 49, wherein said ac voltage applied to said first plurality of electrodes and to said second plurality of electrodes is independently at a frequency from about 0 Hz, or from about 1 Hz, or from about 100 Hz, or from about 1 kHz, or from about 10 kHz, or from about 50 kHz, or from about 100 kHz, or from about 500 kHz, up to about 5 MHz, or up to about 10 MHz, or up to about 15 MHz, or up to about 20 MHz, or up to about 50 MHz, or up to about 100 MHz, or up to about 500 MHz, or ranging from about 10 kHz, or from about 50 kHz, or from about 100 kHz, or from about 500 kHz, up to about 5 MHz, or up to about 10 MHz, or up to about 15 MHz, or up to about 20 MHz.

### Embodiment 51

The device according to any one of embodiments 49-50, wherein said voltage applied to said first plurality of electrodes and to said second plurality of electrodes independently ranges from about close to 0V, or from about 0.001 mV, or from about 0.01 mV, or from about 0.1 mV, or from about 1 mV, or from about 100 mV, or from about 500 mV, or from about 1V, or from about 5V, or from about 10V, up to about 500V, or up to about 100V, or up to about 80V, or up to about 50V, or up to about 40V, or up to maximum voltage above which a fluid in said channel will undergo electrolysis, or ranges from about 1V, or from about 5V, or from about 10V, up to about 100V, or up to about 80V, or up to about 50V, or up to about 40V.

### Embodiment 52

The device according to any one of embodiments 38-51, wherein said first region and said second region each independently range in length up to about 3 cm, or up to about 4 cm, or up to about 5 cm, or up to about 6 cm, or up to about 7 cm, or up to about 8 cm, or up to about 9 cm, or up to about 10 cm, or at least about 25 cm, or at least about 50 cm, or at least about 80 cm, or at least about 100 cm.

### Embodiment 53

The device of embodiment 52, wherein at least a portion of said channel is linear.

### Embodiment 54

The device of embodiment 52, wherein all of said channel is linear.

### Embodiment 55

The device of embodiment 52, wherein at least a portion of said channel is serpentine.

### Embodiment 56

The device of embodiment 55, wherein said first region is serpentine.

### Embodiment 57

The device according to any one of embodiments 55-56, wherein said second region is serpentine.

### Embodiment 58

The according to any one of embodiments 55-57, wherein at least a portion of said channel is serpentine and said channel has a length greater than a linear length of the substrate in which said channel is disposed.

### Embodiment 59

The device according to any one of embodiments 38-58, wherein the average depth of said microfluidic channel ranges from about 0.1 μm, or from about 0.5 μm, or from about 1 μm, or from about 10 μm, or from about 20 μm, or from about 30 μm, up to about 100 μm, or up to about 80 μm, or up to about 60 μm, or up to about 50 μm, or up to about 40 μm.

### Embodiment 60

The device according to any one of embodiments 38-59, wherein the average width of said microfluidic channel ranges from about 0.1 μm, or from about 0.5 μm, or from about 1 μm, or from about 10 μm, or from about 20 μm, or from about 30 μm, or from about 40 μm, or from about 50 μm, or from about 80 μm, or from about 100 μm up to about 500 μm, or up to about 400 μm, or up to about 300 μm, or up to about 200 μm, or up to about 400 μm, or up to about 500 μm, or up to about 1 mm.

### Embodiment 61

The device according to any one of embodiments 38-60, wherein said fluid has a conductivity that ranges from about 10⁻⁶ S/m, or from about 10⁻⁵ S/m, or from about 10⁻⁴ S/m, or from about 10⁻³ S/m, or from about 10⁻² S/m up to about 10 S/m, or up to about 5 S/m, or up to about 2 S/m, or up to about 1.5 S/m, or up to about 1 S/m.

### Embodiment 62

The device according to any one of embodiments 38-61, wherein said fluid comprises a physiological buffer.

### Embodiment 63

The device of embodiment 19, wherein said buffer comprises a mammalian ringer's solution.

### Embodiment 64

The device of embodiment 61, wherein said fluid comprises PBS.

### Embodiment 65

The device according to any one of embodiments 61-64, wherein the conductivity of said fluid is about 1 S/m.

### Embodiment 66

The device according to any one of embodiments 38-65, wherein said hydrodynamic flows are at a rate ranging up to about 10 m/s, or up to about 5 m/s, or up to about 1 m/s, or up to about 50 cm/s, or up to about 20 cm/s, or up to about 15 cm/s, or up to about 11 cm/s, or up to about 10 cm/s, or up to about 8 cm/s, or up to about 5 cm/s, or up to about 3 cm/s, or up to about 1 cm/s, or up to about 500 μm/s, or up to about 250 μm/s, or up to about 100 μm/s, or up to about 50 μm/s, or up to about 30 μm/s, or up to about 20 μm/s, or up to about 10 μm/s.

### Embodiment 67

The device according to any one of embodiments 38-66, wherein said channel is fabricated from a material selected from the group consisting of silicon, a plastic, and an elastomeric material.

### Embodiment 68

The device of embodiment 67, wherein said elastomeric material is selected from the group consisting of polydimethylsiloxane (PDMS), polyolefin plastomers (POPs), perfluoropolyethylene (a-PFPE), polyurethane, polyimides, and cross-linked NOVOLAC® (phenol formaldehyde polymer) resin.

### Embodiment 69

The device of embodiment 67, wherein said channel is fabricated from PDMS.

### Embodiment 70

The device according to any one of embodiments 38-69, wherein said device can separate a 9 μm particle from a 10 μm particle.

### Embodiment 71

The device of embodiment 70, wherein said device can separate a 9 μm particle from a 10 μm particle at a flow rate of 3 cm/s.

### Embodiment 72

The device according to any one of embodiments 38-71, wherein said first region provides a 3D tunable, size-independent, single-stream focusing having sub-micron precision.

### Embodiment 73

The device of embodiment 72, wherein said focusing precision of said first region is less than about 0.2 μm.

### Embodiment 74

The device according to any one of embodiments 38-73, wherein said second region provides a 3D tunable, size-independent, single-stream focusing having sub-micron precision.

### Embodiment 75

The device of embodiment 74, wherein said focusing precision of said second region is less than about 0.2 μm.

### Embodiment 76

The device according to any one of embodiments 72-75, wherein said focusing precision is at a flow rate of about 3 cm/s.

### Embodiment 77

The device according to any one of embodiments 38-76, wherein said device provides sorting purity of greater than about 90%, or greater than about 94%, or greater than about 98%, or greater than about 99%.

### Embodiment 78

The device according to any one of embodiments 38-77, wherein said device is a component of a lab on a chip.

### Embodiment 79

A method of sorting cells, organelles, viruses, particles, molecules, or molecular complexes, said method comprising:

introducing said cells, organelles, viruses, particles, molecules or molecular complexes into a device according to any one of embodiments 38-77; and

capturing said cells, organelles, viruses, particles, molecules, or molecular complexes from said device that have been sorted by size.

### BRIEF DESCRIPTION OF THE DRAWINGS

FIG. 1, panel A schematically illustrates one embodiment of a DEP device for 3D cell focusing. In the illustrated embodiment, the quadro-electrodes are patterned to align with the microchannel through the entire channel. An a.c. signal applied diagonally across these electrodes creates an electric field distribution with a single field minimum in the center of the channel (panel B). Randomly distributed particles are focused into a single stream in the center of the cross section (panel C).

FIG. 2, panels A-C illustrate a schematic design concept and example device of FD-DEP for tunable 3D particle focusing. Panel A: The quadro-electrodes are longitudinally aligned with the microchannel. Different a.c. signals are applied symmetrically or asymmetrically to the four corner electrodes. Randomly distributed particles can be focused into single-stream in the downstream at different cross-section locations where a.c. electric field minima are located. Panel B: A 6 cm-long-channel FD-DEP device with an U.S. 1 dime coin for scale, (b-i) and (b-ii) show the corresponding microscope images of the device in the inlet and outlet. Panel C: Cross section view of the device. A PDMS thin film with an open trench of 80 μm×83 μm (W×H) microchannel is sandwiched between two glass substrates with quadro-electrodes aligned along the entire channel. Scale bar: 80 μm

FIGS. 3A and 3B show electric field simulation and confocal cross-section images of focused particle stream. FIG. 3A: Electric field simulation on the cross-section of a 80 μm×83 μm (W×H) microchannel used for DEP focusing. As shown in (3A-v), when symmetric voltages (V, 0, V, 0) are applied to the quadro-electrodes, electric field minimum is located at the center of the channel. As a differential voltage of either ΔV or V-ΔV replaces one of the applied voltages in (3A-v), the electric field minimum would be offset diagonally as shown in (3A-i) upper-left shift, (3A-iii) upper-right shift, (3A-vii) bottom-left shift, and (3A-ix) bottom-right shift. When differential voltages, ΔV and V-ΔV replace two of the applied voltages in (3A-v), the electric field minimum would offset laterally as shown in (3A-iv) left shift, (3A-vi) right shift, and vertically as shown in (3A-ii) top shift, (3A-viii) bottom shift. The amount of offset can be continuously tuned by adjusting the amplitude of ΔV. In this simulation, liquid medium is assumed having conductivity of 1 S/m with V=10 Vp-p and ΔV=3.1 Vp-p under 1 MHz of excitation frequency. FIG. 3B: Stacked confocal images showing the focused 10 μm polystyrene particles in the downstream where particles are tightly focused at different cross-sectional locations. Particles focusing positions can be continuously tuned laterally (iv,vi), vertically (ii,viii), or diagonally (i,iii,viii,ix) or any other arbitrary locations in the cross section through different combinations of voltages. Images were taken under an average flow speed of 5 cm/s with a maximum 10 Vp-p, 1 MHz, a.c. signals. Scale bar: 10 μm

FIG. 4, panels A-I, illustrates the results of a size-independent focusing experiment. Panels A-C: Numerical simulation of electric field distribution for three different focusing locations in the TDEP channel under the application of three different sets of voltages. Panels D-F: High-speed microscopic images showing four different sizes of polystyrene beads (9 μm, 12 μm, 15 μm, 20 μm) are all focused into a single stream in all cases. Panels G-I: Size independent and tight focusing is proved by the small standard deviations of ±0.46 μm, ±0.33 μm, and ±0.39 μm, respectively. The average flow speed used for this study is 5 cm/s.

FIG. 5, panels A-C show High-speed images showing lateral tunable focusing of THP1 cells. Panel A: THP1 cells were biased as the case shown in FIG. 3A(iv). A maximum voltage of 15.4 Vₚ₋ₚ, 10 MHz is applied to focus cells flowing at a speed of 8.7 cm/s with a 12.5 μm offset from the center. Panel B: Symmetric a.c. voltages (13.8 Vₚ₋ₚ, 10 MHz) are applied as in the case of FIG. 3A(v) to focus cells flowing at a speed of 11 cm/s in the center of a channel. Panel C: Voltages in (panel A) are reversely applied to shift the focusing stream to the other side. Panels D-F: Focusing histograms showing the lateral distribution of cells for (panels A-C). The spatial variations are ±0.76 μm, ±0.82 μm, ±0.89 μm, respectively.

FIG. 6, panels A-D, illustrates viability tests before and after DEP focusing operation. Panel A:13.8 Vp-p, 10 MHz symmetric a.c. signal is applied (Figures, panel B) to focus HeLa cells continuously for long-term and short-term viability tests within an average flow speed of ˜5 cm/s. Panels A-C: For long-term viability study, HeLa cells were collected after the experiment, and put back into cell culture medium DMEM (Dulbecco's Modified Eagle Medium) inside incubator for long-term culturing. Microscopy images of HeLa cells were captured after DEP focusing and cultured at day 1, day 2, and day 3, respectively. From which, HeLa cells can proliferate normally without seeing any viability issues. Panel D: For short term viability study, HeLa cells were collected after the experiment, and stained with Propidium iodide (PI) and verified the viability by flow cytometer. Cells before DEP operation has an average viability of 91.9%, and cells right after DEP operation has an average viability of 85.3%, which shows no major short-term viability issue.

FIG. 7 schematically illustrates one embodiment of a DEP based device for ultra-high precision particle focusing and sorting. Two pairs of quadro-electrodes are longitudinally aligned with the microchannel. Different a.c. signals are applied asymmetrically to the four corner electrodes. Randomly distributed particles of different sizes can be focused into a single stream in the upstream and laterally migrate to new focusing location in the downstream. Larger particles drift faster than the small ones, and get collected into the collection channel.

FIG. 8, panels a-h, schematically illustrates one embodiment of a fabrication process flow using a plastic plate embedded hybrid stamp. Panel a: A SU-8 master is treated with PFOCTS to facilitate later demolding. Panel b: Uncured PDMS mixture is poured on the master, and pressed against the hybrid stamp. Panel c: Due to less PFOCTS treatment on the hybrid stamp compared to the master, the casted PDMS film tends to adhere to the hybrid stamp and allows to be peeled off from the master. Panel d: Film transferred and alignment bonding is achieved through oxygen plasma treatment. Panel e: Remove the support PDMS on the hybrid stamp. Panel f: Dissolve the polystyrene plastic plate in acetone. Panel g: Remove the residual PDMS thin film to complete the removal of a hybrid stamp. Panel h: Align and cover the device with a coverslip with strip electrodes to complete the fabrication process by oxygen plasma bonding.

FIG. 9, panels a-i, shows microscopy images showing the three different particle size mixtures (9 μm+10 μm), (10 μm+12 μm), and (10 μm+15 μm) at upstream focusing (panels a,d,g), downstream migration (panels b,e,h), and collection (panels c,f,i) regions. Larger particles are collected into the upper channel.

FIG. 10, panels A-F shows particle position histograms at locations in FIG. 7(ii) and FIG. 7(iii) are shown in (A,B) for the 10 μm+15 μm mixture, (C,D) 10 μm+12 μm, and (E,F) for 9 μm+10 μm. Particle positions in the upstream (A,C,E) have standard deviations of ±0.11 μm, ±0.13 μm, and ±0.18 μm, respectively.

FIG. 11, panels a-d, shows rare cell sorting results of GFP-Hela cell spiked into lysed blood. The HeLa cell purity before and after DEP sorting purity is 0.4% (c) and 94% (d) with viability 94% and 92.1%, respectively. This corresponds to a 234 fold enrichment.

FIG. 12, panels a-f, shows high-speed images showing the lateral tunable focusing for 10 μm polystyrene particles and THP1 cells in regular physiological buffer (PBS, conductivity ˜1 S/m) in high speed flow. (b) Particles and (e) cells are focused in the center at ˜11 cm/s and ˜8.7 cm/s when symmetric a.c. signal, 13.8 Vp-p, 1 MHz and 21.2 Vp-p, 10 MHz are applied respectively. (a, c) and (d, f) show the lateral tunable focusing for particles and cells, respectively. Scale bar: 20 μm

### DETAILED DESCRIPTION

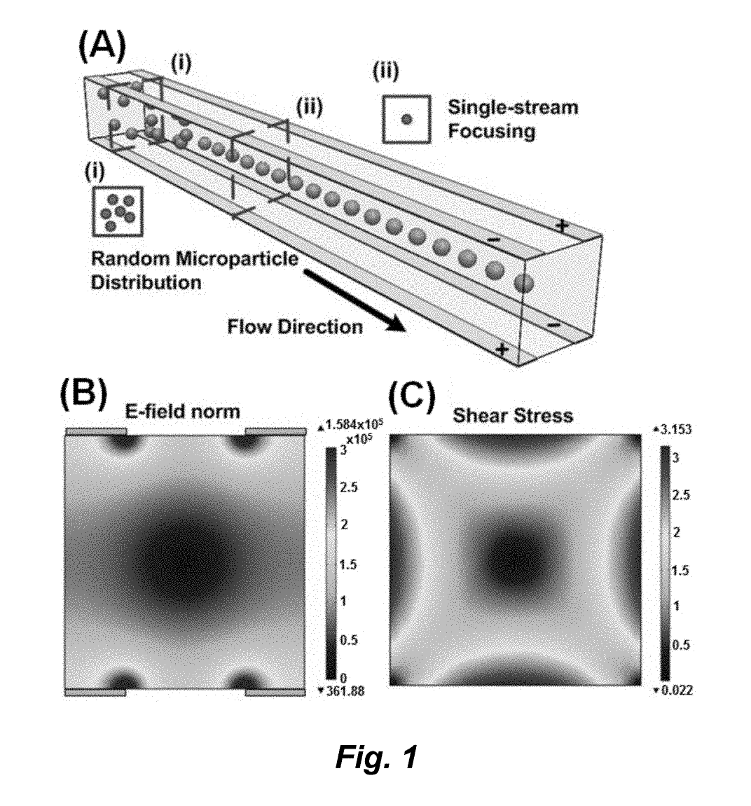

In various embodiments a novel dielectrophoretic (DEP) mechanism for tunable, sheathless, three dimensional, and single-stream microparticle and cell focusing in high-speed flows is provided. In certain embodiments, it is realized by fabricating a 3D microfluidic device with two substrates (e.g. glass substrates sandwiching a thin and open microfluidic channel (e.g., a PDMS channel). Electrodes are laid out to provide DEP forces completely perpendicular to hydrodynamic flows along the channel (see, e.g., FIG. 1). It is believed that this new approach provides, for the first time, real-time 3D tuning of particle/cell focusing locations by simply changing voltage combinations applied to the electrodes. Furthermore, microparticle and cell (e.g., mammalian cell) focusing cab be achieved at flow speeds up to 11 cm/s (three orders of magnitude higher than prior DEP focusing works) in regular physiological buffers, without medium swapping to low ionic isotonic buffers as in most prior DEP based devices.

In certain embodiments a device is provided for focusing cells, viruses, organelles, particles, molecules. molecular complexes, and the lie in a microfluidic channel, where the device comprises a microfluidic channel comprising a plurality of electrodes disposed on surfaces of the channel to provide three-dimensional spatially tunable tunnel electric field minimum for dielectrophoretic (DEP) forces that are perpendicular to hydrodynamic flows along the channel. In certain embodiments the device comprises a fluid within the channel providing hydrodynamic flow along the channel. In certain embodiments the device is configured to apply voltages to the electrodes to provide an spatially adjustable electric field minimum or electric field pattern that is programmable by the voltage combinations on the electrodes. In certain embodiments the focusing is obtained without sheath flow. In certain embodiments the microfluidic channel comprises a plurality of electrodes disposed to provide dielectrophoretic (DEP) forces that are perpendicular to hydrodynamic flows along the channel; and the device is configured to apply voltages to the electrodes to provide an electric field minimum that is not centered in said microfluidic channel.

In certain embodiments the device is device is configured to apply voltages independently to each of the electrodes. In certain embodiments the device comprises two pairs of electrodes disposed parallel to each other around the microfluidic channel. In certain embodiments the plurality of electrodes comprises electrodes disposed along each side of the microfluidic channel at or near the top of the channel and electrodes disposed along each side of the microfluidic channel at or near the bottom of said channel. In certain embodiments the plurality of electrodes comprises electrodes disposed along the midline of each side of the microfluidic channel and along the midline of the top and bottom of the channel.

In certain embodiments the device is configured to provide, and/or applies an a.c. voltage to one or more, or to two or more, or to three or more, or to all of the electrodes.

In certain embodiments the device is configured to provide the voltages described above by integration of a voltage source (e.g., one or more power supplies, signal generators, etc.). In certain embodiments the device is configured to provide the voltages described above by integration of voltage regulators that can adjust one or more externally applied voltages. In certain embodiments the device is configured to provide the voltages described above by electrical coupling to one or more external voltage sources (e.g., power supplies).

In certain embodiments the device is configured to apply to the electrodes and/or the voltage applied to the electrodes is independently (e.g., independently regulated voltage(s)) at a frequency ranging from about 0 Hz, or from about 1 Hz, or from about 100 Hz, or from about 1 kHz, or from about 10 kHz, or from about 50 kHz, or from about 100 kHz, or from about 500 kHz, up to about 5 MHz, or up to about 10 MHz, or up to about 15 MHz, or up to about 20 MHz, or up to about 50 MHz, or up to about 100 MHz, or up to about 500 MHz, or ranging from about 10 kHz, or from about 50 kHz, or from about 100 kHz, or from about 500 kHz, up to about 5 MHz, or up to about 10 MHz, or up to about 15 MHz, or up to about 20 MHz.

In certain embodiments the device is configured to apply to the electrodes and/or the voltage applied to the electrodes is independently (e.g., independently regulated voltage(s)) that range from about 0V, or from about 0.001 mV, or from about 0.01 mV, or from about 0.1 mV, or from about 1 mV, or from about 100 mV, or from about 500 mV, or from about 1V, or from about 5V, or from about 10V, up to about 500V, or up to about 100V, or up to about 80V, or up to about 50V, or up to about 40V, or up to maximum voltage above which a fluid in said channel will undergo electrolysis, or ranges from about 1V, or from about 5V, or from about 10V, up to about 100V, or up to about 80V, or up to about 50V, or up to about 40V.

In certain embodiments the electrodes are configured (e.g., the voltages applied to the electrodes are selected) to provide a field minimum at or near a lower or upper corner (diagonal region) of the channel. In certain embodiments the electrodes are configured (e.g., the voltages applied to the electrodes are selected) to provide a field minimum at or near one side or near the top or bottom of the channel.

In certain embodiments the microfluidic channel length is at least about 1 μm, or at least about 10 μm, or at least about 100 μm, or at least about 500 μm, or at least about 1 cm, or at least about 2 cm, or at least about 3 cm, or at least about 4 cm, or at least about 5 cm, or at least about 6 cm, or at least about 7 cm, or at least about 8 cm, or at least about 9 cm, or at least about 10 cm, or at least about 25 cm, or at least about 50 cm, or at least about 80 cm, or at least about 100 cm. In certain embodiments the microfluidic channel is linear. In certain embodiments the microfluidic channel or a portion of the channel is serpentine. In certain embodiments the microfluidic channel is serpentine and has a length greater than a linear length of the substrate in which said channel is disposed.

In certain embodiments the wherein the average depth of the microfluidic channel ranges from about 0.1 μm, or from about 0.5 μm, or from about 1 μm, or from about 10 μm, or from about 20 μm, or from about 30 μm, up to about 100 μm, or up to about 80 μm, or up to about 60 μm, or up to about 50 μm, or up to about 40 μm. In certain embodiments the average width of said microfluidic channel ranges from about 0.1 μm, or from about 0.5 μm, or from about 1 μm, or from about 10 μm, or from about 20 μm, or from about 30 μm, or from about 40 μm, or from about 50 μm, or from about 80 μm, or from about 100 μm up to about 500 μm, or up to about 400 μm, or up to about 300 μm, or up to about 200 μm, or up to about 400 μm, or up to about 500 μm, or up to about 1 mm.

### Sorter.

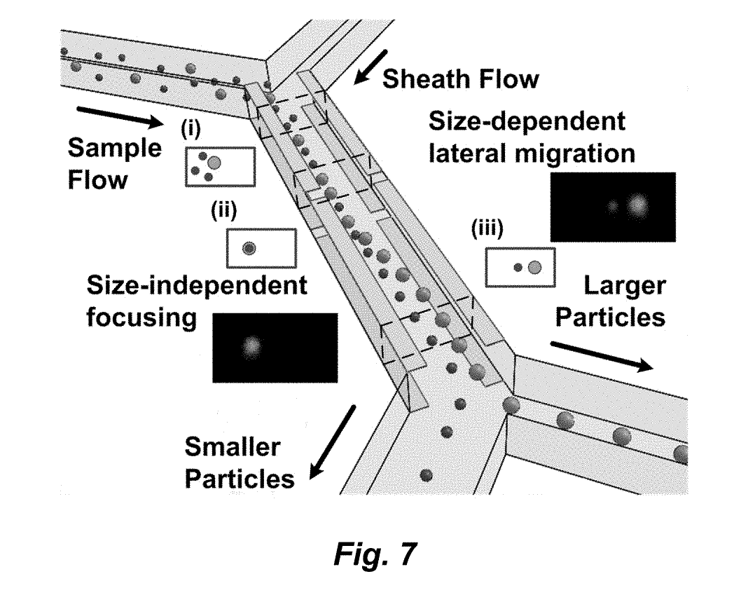

In certain embodiments devices for sorting cells, organelles, viruses, particles, molecules, or molecular complexes are provided. In certain embodiments the device comprises a microfluidic channel comprising a first region comprising a first plurality of electrodes disposed to provide dielectrophoretic (DEP) forces that are perpendicular to hydrodynamic flows along the first region of the channel (e.g., as described above); and a second region downstream from the first region comprising a second plurality of electrodes disposed to provide dielectrophoretic (DEP) forces that are perpendicular to hydrodynamic flows along the second region of the channel (e.g., as described above; and where the device is configured to apply voltages to first plurality of electrodes to provide an electric field minimum at a first location in the cross-section of the channel and to apply voltages to the second plurality of electrodes to provide an electric field minimum at a second location in the cross-section of the channel, where the first location and the second location are different locations in the cross-section of the channel (see, e.g., FIG. 7). In certain embodiments the first location is the cross-section at or near a wall of the channel and the second location is at or near the opposite wall of the channel. In certain embodiments the first location is at or near a corner of the channel and the second location is a corner of the channel diagonally opposite. In certain embodiments the second region of the channel diverges into a plurality of channels whereby different size particle are diverted into different channels providing particle having different size or size distribution in each different channel of the plurality of channels. In certain embodiments the second region diverges into 2, 3, r, 5, 6, 7, 8, 9, 10, or more different channels.

In certain embodiments the device comprises a port or channel for introducing the cells, organelles, viruses, particles, molecules or molecular complexes into the first region of the channel. In certain embodiments the device comprises a port or channel for introducing a sheath flow into the microfluidic channel. In certain embodiments the device has sufficient resolution to separate a 9 μm particle from a 10 μm particle, e.g., at a flow rate of 3 cm/s.

In certain embodiments the first region and/or the second region provides a 3D tunable, size-independent, single-stream focusing having sub-micron precision. In certain embodiments the focusing precision is less than about 0.2 μm (e.g., at a flow rate of about 3 cm/s). In certain embodiments the device provides sorting purity of greater than about 90%, or greater than about 94%, or greater than about 98%, or greater than about 99%.

In various embodiments the device can be incorporated with other components. In certain embodiments the device is a component of a lab on a chip.

In certain embodiments methods of sorting cells, organelles, viruses, particles, molecules, or molecular complexes are provided where the methods involve introducing the cells, organelles, viruses, particles, molecules, or molecular complexes into a sorting device as described and claimed herein, and capturing the cells, organelles, viruses, particles, molecules, or molecular complexes from the device that have been sorted by size.

### Device Fabrication.

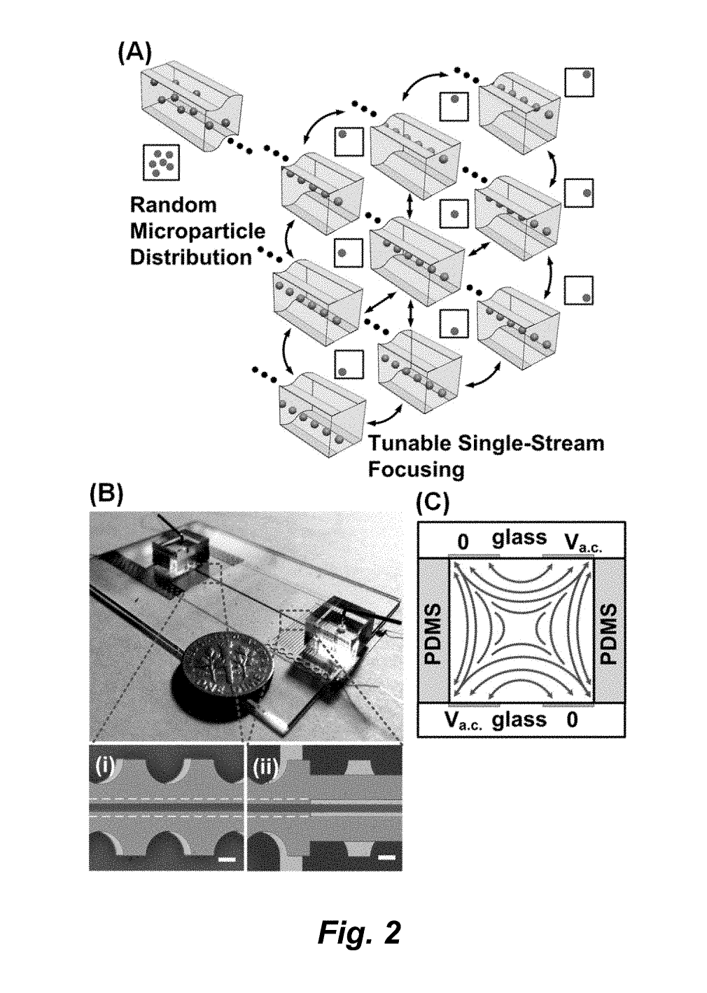

To fabricate the device, utilize a new fabrication method previously reported by our group (see, e.g., Kung et al. (2015) Lab Chip, 15: 1861-1868) was used. A large area (6 cm×2.2 cm) PDMS thin film with an open microchannel (H W, 83 μm 80 μm) is sandwiched between a glass slide and a coverslip with strip electrodes aligned to the four corners of the channel. This allows the creation of a three-dimensional electric field profile through the entire focusing channel. FIG. 2, panel A, shows a schematic illustration of one embodiment of the platform. The principle of tunable focusing is realized by applying different combinations of ac voltages to the four corner electrodes to offset the electric potential minima in the channel cross section as shown therein.

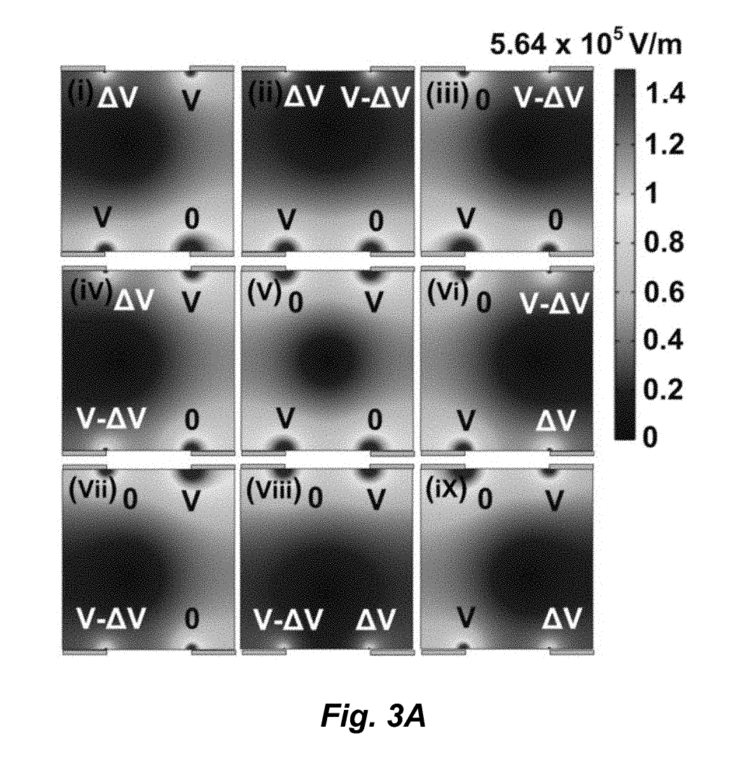

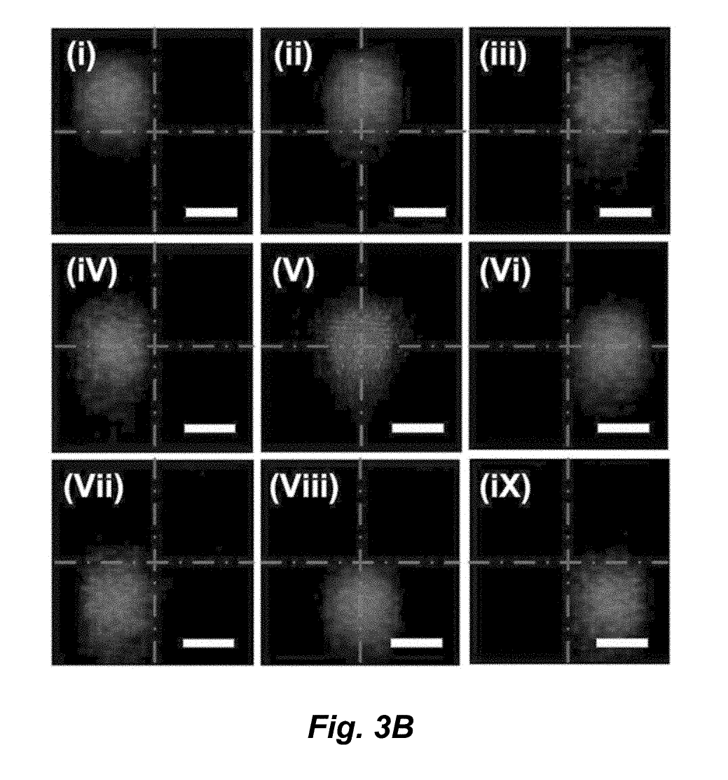

FIG. 3B demonstrates the tunable 3D particle focusing functions by showing the confocal fluorescence images (center (FIG. 3B(e)), lateral (FIG. 3B(d, f)), vertical (FIG. 3B(b, h), and diagonal (FIG. 3B(a, c, g, i)) tunable focusing) at the downstream of the channel (x=4 cm). Since particles and cells are focused at a potential minimum where there is zero electric field, electric field impacts on focused cells can be dramatically reduced.

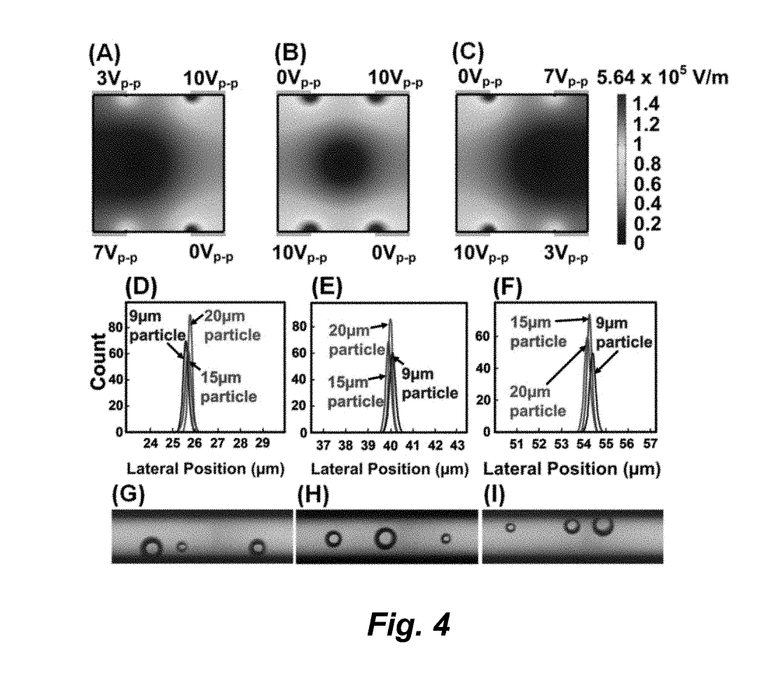

The focusing positions of microparticles can be precisely predicted by numerical simulation in COMSOL (FIG. 4 (panels A-C)) and verified experimentally by the corresponding histograms plots in FIG. 4 (panels D-F). In FIG. 4 (panels B, E), particles are focused at the center of the channel when symmetric voltages are applied. In FIG. 4 (Panels A, D) and FIG. 4 (panels C, F, f), the focusing positions are shifted by 14 μm toward the left and the right, respectively, when asymmetric voltages are applied.

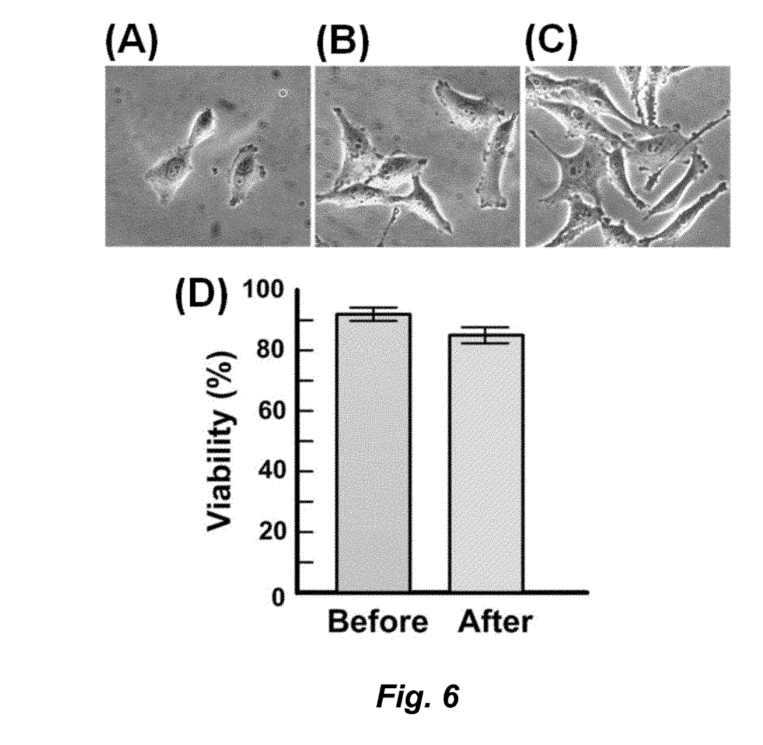

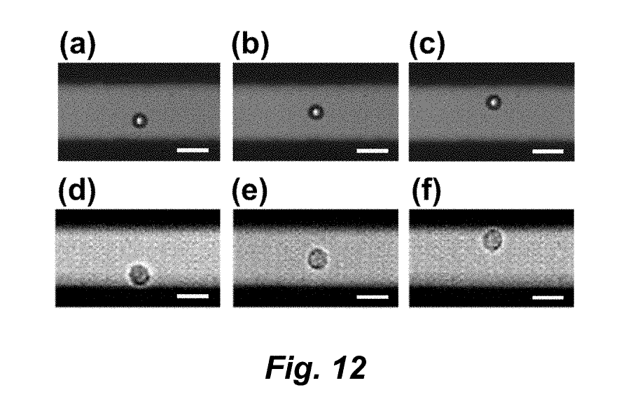

The snapshot images (FIG. 12) captured by a high-speed camera show the lateral tunable focusing of 10 μm polystyrene beads and THP1 cells in a physiological buffer (PBS, conductivity ˜1 S/m). A 13.8 Vp-p, 1 MHz a.c. signal is applied in FIG. 12, panel (b), to focus beads flowing at a 11 cm/s speed. In addition, an a.c. signal of 21.2 Vp-p, 10 MHz is applied in FIG. 12, panel e, to focus THP1 cells at a speed of 8.7 cm/s. FIG. 12, panels a,c, and FIG. 12, panels d, f, show the lateral tunable focusing for beads and cells, respectively. The viability right after the DEP operation is 93.2%. Multi-day cell viability has also been conducted. FIG. 6, panels A-C, shows microscopy images of HeLa cells captured after DEP focusing and cultured at day 0, day 2, and day 4, respectively.

In another illustrative, but non-limiting embodiment the DEP mechanism described above, is exploited for ultra-high precision microparticle and cell focusing and separation in high-speed flows. For the first time, particle size differences as small as 1 μm can be separated with high purity (>90%). This is realized by a 3D tunable, size-independent, single-stream sub-micron precision (variation <0.2 μm) focusing function. As illustrated in FIG. 7, a microfluidic channel is provided comprising, in certain embodiments, two different regions each having independently tunable electric field patterns that can be manipulated by simply changing voltage combinations applied to sets of electrodes. A first set of electrodes can be used to focus particles and/or cells to a first location in an upstream (first region) of the microfluidic channel, and a second set of electrodes can be used to focus particles and/or cells at a different location in the downstream (second region) of the microfluidic channel. As different size particle or cells migrate at different speeds, the cells or particles are readily separated as they migrate. Microparticle and mammalian cell focusing and separation have been achieved at flow speeds up to 3 cm/s in high conductivity regular physiological buffers

One of skill in the art would recognize that the embodiments described herein are illustrative and non-limiting. For example, in certain embodiments, electrodes could be disposed the middle of the top and bottom and at the middle of each side of the microfluidic channel. Similarly, the microfluidic channel can be fabricated in or from any of a number of materials including, but not limited to silicon/glass, a plastic, an elastomeric material (e.g., polydimethylsiloxane (PDMS), polyolefin plastomers (POPs), perfluoropolyethylene (a-PFPE), polyurethane, polyimides, and cross-linked NOVOLAC® (phenol formaldehyde polymer), and the like). Using the teachings provided herein, numerous variations of the illustrated and described devices and methods will be available to one of skill in the art.

### EXAMPLES

The following examples are offered to illustrate, but not to limit the claimed invention.

### Example 1

### Tunnel Dielectrophoresis for Tunable, Single-Stream Cell Focusing in High Speed Microfluidic Flows in Physiological Buffers

Here, we demonstrate a novel tunnel dielectrophoresis (TDEP) mechanism for tunable, sheathless, three dimensional, and single-stream microparticle and cell focusing in high-speed flows. It is realized by fabricating a 3D microfluidic device with two glass substrates sandwiching a thin and open PDMS channel (see, e.g., Kung et al. (2015) Lab Chip, 15: 1861-1868 for an illustrative fabrication protocol). Electrodes are laid out to provide DEP forces completely perpendicular to the hydrodynamic flow along a channel that can range in length up to several centimeters (e.g., up to about 1 cm, or up to about 2 cm, or up to about 3 cm, or up to about 4 cm, or up to about 5 cm, or up to about 6 cm, or up to about 7 cm, or up to about 8 cm, or up to about 9 cm, or up to about 10 cm. This provides a long DEP interaction such that microparticles and cells have sufficient time to migrate to the focused stream even in high-speed flows. FIG. 2 shows a schematic of one illustrative TDEP device. As illustrated, the device comprises two pairs of electrodes disposed parallel to each other around the channel. Four independently tunable a.c. signals are applied to these quadro-electrodes to create a tunnel-shape potential energy landscape with a cross-sectional single minimum along the channel. The location of the electric field minimum, as well as the particle and/or cell focusing location, can be real-time adjusted in two dimensions across the cross section by changing the voltage combinations applied to these electrodes. Of note is that, due to the completely perpendicular and decoupled design between the DEP and hydrodynamic forces, the focusing location is flow speed independent. As long as the channel is of sufficient length to permit migration of the cells and/or particles to the field minimum, they will all migrate to the same location in the channel regardless of flow speed and/or particle size. The focused location is also particle type independent as long as the particles show negative DEP responses to the applied electrical signals. In addition, microparticles and mammalian cells focusing can be achieved in physiological buffers (e.g., in a Ringer's solution) without medium swapping to low ionic buffers prior to DEP operations.

### Device Design and Operation Principle

Dielectrophoresis refers to the interaction force between a non-uniform electric field and the dipole moment it induces on a polarizable object. The magnitude of DEP force on a spherical particle can be expressed by the following formula derived based on a diploe approximation:

F_{DEP}⁽¹⁾=2π∈ₘR³Re[CM(ω)×∇Ē²] (1)

where F_{DEP}⁽¹⁾ refers to the DEP force, £ₘ the permittivity of the medium surrounding the sphere, R the radius of the particle, w the radian frequency of the applied field, and Ē the applied electric field. CM is the Clausius-Mossotti (CM) factor given by

$$CM = \frac{{\underline{ɛ}}_{p} - {\underline{ɛ}}_{m}}{{\underline{ɛ}}_{p} + 2 {\underline{ɛ}}_{m}} \qquad ( 2 )$$

where and ∈ₚ and ∈ₘ are the complex permittivities of the particle and the medium, respectively, and ∈=∈+σ/(jω), where ∈ is the permittivity, and σ the conductivity. The magnitude of DEP force is linearly proportional to the gradient of electric field strength (E²) and the volume of particles. For particles more polarizable than the medium, Re [CM]>0, they experience positive DEP forces that move them toward the strong electric field region. On the other hand, if Re[CM]<0, particles migrate to the weak electric field region.

DEP manipulation on mammalian cells is usually conducted in low ionic isotonic buffers for several reasons. One is that different types of mammalian cells suspended in low ionic buffers (0.01 S/m˜0.1 S/m) can show very distinct dielectric signatures and CM curves, which makes cell sorting easier to perform. Second, higher voltage can be applied to electrodes to generate larger DEP forces on cells without inducing electrolysis on electrodes or causing significant heating. Yet, suspending cells in isotonic buffers with low ionic strength over a long time may impact cells' viability.

The challenge of manipulating mammalian cells in regular physiological buffers is that only negative DEP forces can be induced on cells since the Re[CM] is negative and small over the entire frequency spectrum. In addition, high frequency, typically 1 MHz to 10 MHz, and low voltage operation is required to prevent electrolysis on electrodes. This limits the DEP forces that can be induced on mammalian cells in physiological buffers. The design of TDEP has several unique features to solve these challenges. TDEP is for focusing particles and cells with negative DEP forces. The four independently voltage controlled quadro-electrodes ensure that there is only one potential minimum in the cross section of a microfluidic channel. The location of potential minimum can be real-time adjusted by changing the voltage combinations applied to electrodes. In TDEP, there is only one focused position for all particles, regardless of their sizes and types, as long as they show negative DEP responses. This is an important feature for applications, such as flow cytometers, that need all particles to flow at the same speed, pass through the same location in a channel for light detection or imaging, and be at the same reference position for downstream applications. The extremely long DEP interaction distance throughout the entire channel allows cells in physiological buffers with weak negative DEP forces to have sufficient time to migrate to the focused location in high-speed flows. For example, if the DEP induced cell migration speed is 80 μm/sec, and the channel width and height are both 80 μm. It takes an average of 0.5 second for cells near the channel wall to migrate to the center of the channel. If the DEP interaction distance is 6 cm, the length used in TDEP devices presented in this paper, single stream focusing can be realized at an average flow speed of 12 cm/sec, three orders of magnitude higher than prior DEP focusing devices that operate at a flow speed<100 μm/sec in regular physiological buffer (Gao et al. (2012) Analyst, 137(22): 5215-5221). Long DEP channel can be easily fabricated by utilizing a serpentine channel design. However, running cells at a particle Renold's number (Rₚ)>0.5 (Carlo et al. (2007) Proc. Natl. Acad. Sci. USA, 104(48): 18892-18897; Hur et al. (2010) Lab Chip, 10(3): 274-280) (corresponding flow velocity ˜40 cm/s in this design) in a microfluidic channel may encounter inertial effects that affect the DEP focusing functions. More studies are required to understand the coupling between inertial forces and DEP forces in this regime.

Another unique feature of TDEP is that the DEP forces on cells and particles only exist in the direction perpendicular to the channel and completely decouple from the hydrodynamic forces that carry particles to flow along a streamline in the channel. This means that particles' transverse migration driven by DEP forces is not affected by the flow speeds in channels. Unlike prior DEP devices that utilized titled electrode design for cell focusing, DEP forces and hydrodynamic forces are not decoupled. Particle focusing behavior is highly dependent upon flow speeds, particle sizes, and particle types. (Han et al. (2008) Lab Chip, 8(7): 1079-1086; Hu et al. (2005) Proc. Natl. Acad. Sci. USA, 102(44): 15757-15761; Kim et al. (2008) Anal. Chem., 80(22): 8656-8661; Kim et al. (2007) Proc. Natl. Acad. Sci. USA, 104(52): 20708-20712).

### Results

3D Tunable Focusing

The four independently controlled quadro-electrodes provide the real-time tuning function to adjust the location of potential minimum and particle focused stream. FIG. 3a shows the COMSOL numerical simulation results of electric field distribution across a rectangular channel under different voltage combinations. When symmetric voltage signals are applied (FIG. 3a-v), the electric field minimum is located at the center of the channel. When one of the voltages is changed to ΔV or V-ΔV, where ΔV<V, the focusing position will shift in one of the diagonal directions as shown in FIG. 3a-i,iii,vii,ix. For lateral or vertical shifts, two of the voltages are changed to ΔV and V-ΔV. Depending on which two electrodes are picked, lateral shifts are shown in FIG. 3a-iv, vi, and vertical shifts in FIG. 3a-ii,viii. The amount of shift depends on the amplitude of ΔV and can be continuously tuned. The tuning range, in principle, can be as large as the entire channel cross section. For example, if the ΔV in FIG. 3a-iii is equal to V, the electric field minimum will be at the upper right corner of the channel. In real applications, shifting particles too close to walls may not be preferred since particle speed will be significantly slowed down due to the parabolic flow velocity profile in a microfluidic channel.

These simulation results are confirmed by experimental data shown in FIG. 3b that shows the stacked confocal images of polystyrene beads flowing through a rectangular TDEP channel under the application of different voltage combinations. The experiment was conducted using a 6 cm long TDEP channel. The confocal images were taken at 4 cm in the downstream channel location where beads were already tightly focused into a single stream. The TDEP channel is 80 μm wide and 83 μm high; the average flow speed is 5 cm/sec; the maximum a.c. voltage applied is 10 Vₚ₋ₚ at 1 MHz frequency; and the solution was a PBS buffer with a conductivity of 1 S/m. These experimental results not only prove that particle focusing in TDEP is electrically tunable but also show that there is only one electric field minimum across the channel for single stream focusing in all cases shown.

Size Independent Focusing

In FIG. 4, we demonstrated the function of size-independent particle focusing. The focusing positions of microparticles can be precisely predicted by COMSOL numerical simulation (FIG. 4, panels A-C) and verified experimentally by the high-speed microscopic images shown in FIG. 4, panels G-I, demonstrating that different sizes of particles (9 μm, 15 μm, 20 μm) are all focused tightly into a single stream with submicron position variations in all cases (FIG. 4, panels D-F). Standard variations of ±0.46 μm, ±0.33 μm, and ±0.39 μm were found for the cases of 14 μm shift toward the left, zero shift, and 14 μm shift to the right, respectively (FIG. 4, panels G-I).

Mammalian Cell Focusing and Viability Study

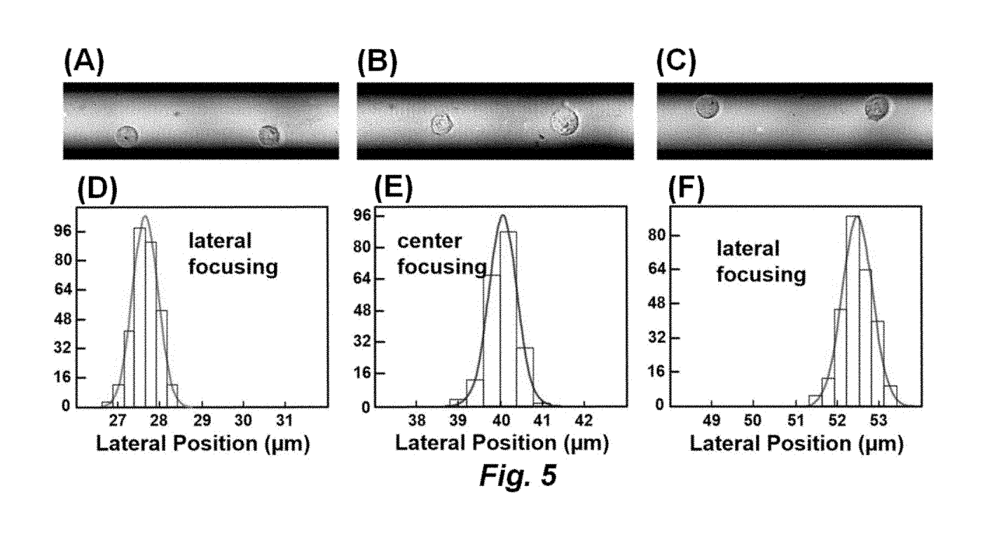

The snapshot images in FIG. 5a-c captured by the high-speed camera show the lateral tunable focusing of THP1 cells in a physiological buffer (PBS, conductivity ˜1 S/m). A 13.8 Vₚ₋ₚ, 10 MHz symmetric a.c. signal is applied in FIG. 5b to focus cells flowing at a speed of 11 cm/s. Because of the size- and type-independent focusing nature of the TDEP platform, different sizes of cells can be well focused as shown in the histogram FIG. 5e, in which the standard deviation falls within 0.82 μm for center focusing (symmetric voltage excitation). For non-symmetric voltage excitation, an a.c. signal sets with a maximum 15.4 Vₚ₋ₚ, 10 MHz are applied to focus THP1 cells flowing at a speed of 8.7 cm/s into a stream with a 12.5 um lateral offset as shown in FIG. 5a, c. FIG. 5d and FIG. 5f show the focusing histogram of FIG. 5a and FIG. 5c with variations of ±0.76 μm and ±0.89 μm, respectively.

In order to verify the viability effect before and after DEP focusing operation, short-term and long-term viability tests were carried out on HeLa cells. In the short-term viability test, HeLa cells in condition of FIG. 5b were collected after the experiments and compared with cells without focusing operation as shown in FIG. 5d. Experiment was carried out continuously for one hour with each cell passing through the channel within less than one second. Right after the experiment, cells were stained with Propidium iodide (PI) and verified the viability by flow cytometer. Cells before DEP operation has an average viability of 91.9%, and cells right after DEP operation has an average viability of 85.3%, which shows no major short-term viability issue. As for the long-term viability test, HeLa cells were used for the DEP operation. Under the same experimental condition of FIG. 5b, HeLa cells right after the focusing experiment were put back into cell culture medium DMEM (Dulbecco's Modified Eagle Medium) inside incubator for long-term culturing. FIG. 5a-c shows microscopy images of HeLa cells captured after DEP focusing and cultured at day 1, day 2, and day 3, respectively. From which, HeLa cells can proliferate normally without seeing any viability issues.

### Example 2

### Tunable, High-Speed, and Three-Dimensional Microfluidic Device for Ultra-High Precision Size-Based Particle Separation

To achieve continuous and high size precision sorting two stages of particle manipulation methodologies can be utilized. In the first stage, all particles, regardless of their different sizes, are three-dimensionally focused into a single-stream in a continuous flow such that different sizes of particles have exactly the same reference position. In the second stage, particles migrate to a new focusing position under a new set of boundary conditions. Due to different forces acting on particles of different sizes, particles of different migration speeds can be sorted out and collected. A size-independent, tight upstream particle focusing is key for the downstream high purity sorting of particles with minor size differences.

Here, we demonstrate a novel DEP device that can provide a microfluidic device capable of providing tunable and particle size-independent, sub-micron precision single-stream focusing in the upstream (Kung et al. (2015) Tunable, Sheathless, and Three Dimensional Single-Stream Cell Focusing in High Speed Flows, in The 19th International Conference on Miniaturized Systems for Chemistry and Life Sciences, Gyeongju, Korea), followed by high purity sorting of particles with size difference smaller than 1 μm in the downstream. Furthermore, such sorting was achieved at flow speeds up to 3 cm/s in regular physiological buffers, without the need to swap the medium to a low ionic isotonic buffer, which may affect cells' viability and physiological conditions.

### Device Design.

Dielectrophoresis (DEP) is a phenomenon in which a particle in a non-uniform electric field can experience an electrostatic force moving it towards a stronger electric field region if it is more polarizable than the medium, or to a weaker electric field region if the particle is less polarizable than the medium.

FIG. 7 shows the schematic of a 3D microfluidic device capable of performing tunable, sheathless, three dimensional, and single-stream microparticle and cell focusing in high-speed flows. It is realized by sandwiching a thin and open PDMS channel between two glass substrates. Electrodes are laid out to provide DEP forces completely perpendicular to hydrodynamic flows along the entire channel (Kung et al. (2015) Tunable, Sheathless, and Three Dimensional Single-Stream Cell Focusing in High Speed Flows, in The 19th International Conference on Miniaturized Systems for Chemistry and Life Sciences, Gyeongju, Korea; Kung et al. (2014) Flow-Decoupled Dielectrophoresis for Sheathless 3D Focusing in High Speed Flows, in The 18th International Conference on Miniacturized Systems for Chemistry and Life Sciences, San Antonio, Tex., U.S.A.). The principle of tunable electric field pattern is achieved by applying different combinations of ac voltages to four corner electrodes to offset the electric field potential minima in the channel cross section. In the upstream focusing section (FIG. 7(ii)), particles of different sizes are all focused to a single-stream to one side of the channel. In the downstream separation section (FIG. 1(iii)), focusing spot is programmed to offset to the other side. Larger particles drift faster laterally than smaller ones and migrate into the collection channel. Confocal fluorescence images show the cross-sectional particle position in the upstream (FIG. 7 (ii)) and downstream sections (FIG. 7 (iii)).

### Device Fabrication

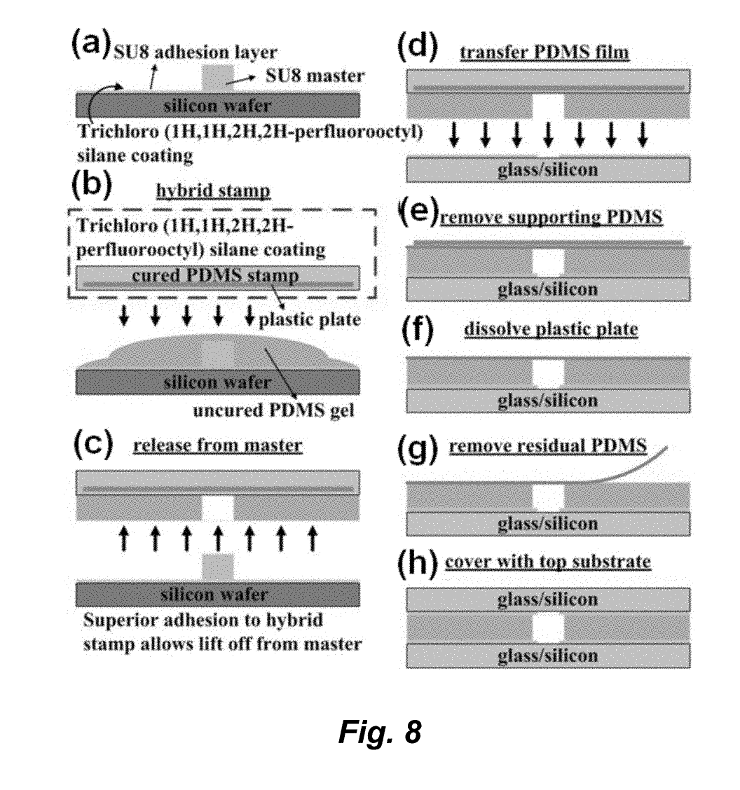

FIG. 8 shows the schematic of the microfabrication process flow of the device, a process previously demonstrated in (Kung et al. (2014) Lab Chip, 15: 1861-1868).

Step 1: Fabrication of master molds. SU-8 mold masters on silicon wafers were fabricated using photolithography (FIG. 8 (a)). All masters need to be surface treated with trichloro (1H,1H,2H,2H-perfluorooctyl) silane (97%, Sigma-Aldrich, USA), also called PFOCTS, to facilitate later demolding.

Step 2: Fabrication of hybrid stamps. It starts from preparing the Sylgard 184 silicone elastomer mixture (Dow Corning Corporation, Miland, USA). The weight ratio of Base:Curing agent is 10:1. Few drops of this mixture are poured into a petri dish. A suitable size of polystyrene plastic plate is cut and pressed against the bottom of the petri dish under a pressure of 3 psi. A thin layer of polydimethylsiloxane (PDMS) with a thickness of roughly 30 μm is formed between the petri dish and the plastic plate. Additional uncured PDMS is poured to fill up the petri dish, and followed by a curing step at 60° C. in an oven for 12 hours. A hybrid stamp is formed when the plastic plate together with a thin PDMS layer on its surface is peeled off from the petri dish (FIG. 8 (b)). The hybrid stamp is also surface treated with PFOCTS as in Step 1 for 6 hours. To fabricate a PDMS thin film with through-layer structures, uncured PDMS is poured onto the master mold, pressed by the hybrid stamp under a pressure of 4 psi, and cured at 50° C. in an oven for an hour.

Step 3: Demolding PDMS films from the master mold. During the demolding process, the cured PDMS thin film has stronger adhesion to the hybrid stamp than the master mold since more PFOCTS is coated on the master mold due to a longer treatment time (FIG. 8(c)).

Step 4: Transfer the PDMS thin film. Oxygen plasma treatment is performed on both the PDMS thin film on the hybrid stamp and the substrate with strip electrodes to be bonded. The alignment between channel and strip electrode is needed. (FIG. 8(d)).

Step 5: Removing the hybrid stamp. It starts from peeling off the bulk PDMS part on the plastic plate (FIG. 8(e)), and then dissolving the polystyrene plastic plate in an acetone bath for 4 hours (FIG. 8 (f)). This leaves a thin residual PDMS film on the substrate that can be easily peeled off from the device due to prior PFOCTS treatment (FIG. 8(g)) to finish the transfer. This mechanically gentle releasing technique allows us to transfer PDMS thin film with fragile substrates, such as a high aspect ratio vertical wall.

Step 6: Align and cover the device with a top coverslip with strip electrodes by oxygen plasma bonding to finish the device fabrication. (FIG. 8(h)).

### EXPERIMENTAL RESULTS

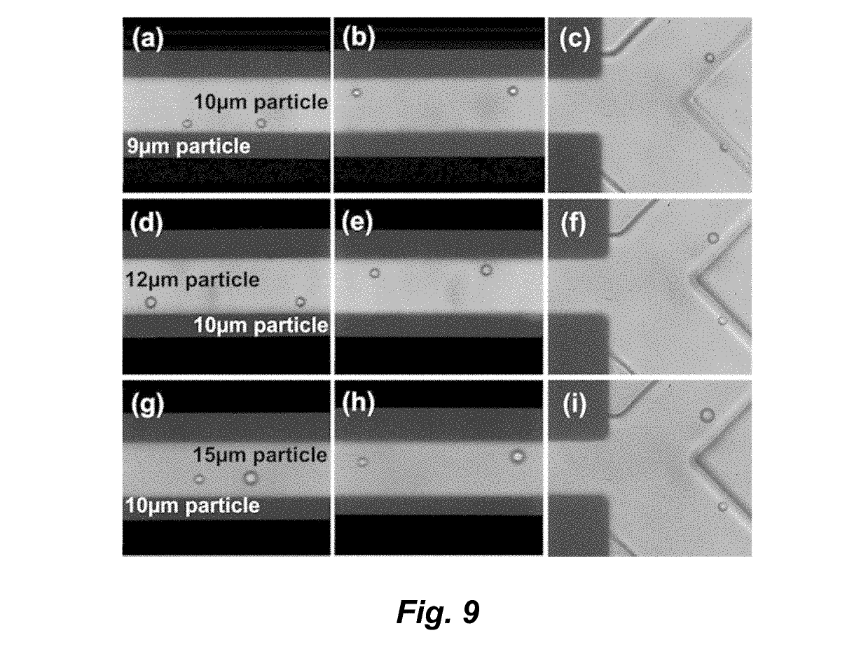

FIG. 9 shows the microscope images of three different particle size mixtures (9 μm+10 μm), (10 μm+12 μm), and (10 μm+15 μm) at upstream focusing (FIG. 9 (a,d,g)), downstream migration (FIG. 9(b,e,h)), and collection (FIG. 9(c,f,i)) regions, respectively. Table 1 shows the size-based sorting results of the three different cases in FIG. 9.

TABLE 1
Size-based sorting results (purity represents the concentration
of larger-sized particle).

| | Before Sort | After Sort |
|---|---|---|
| Beads Mix | Purity | Purity |
| 9 μm + 10 μm | 1.2% | 94.2% |
| 10 μm + 12 μm | 1.8% | 98.8% |
| 10 μm + 15 μm | 1.6% | 99.1% |

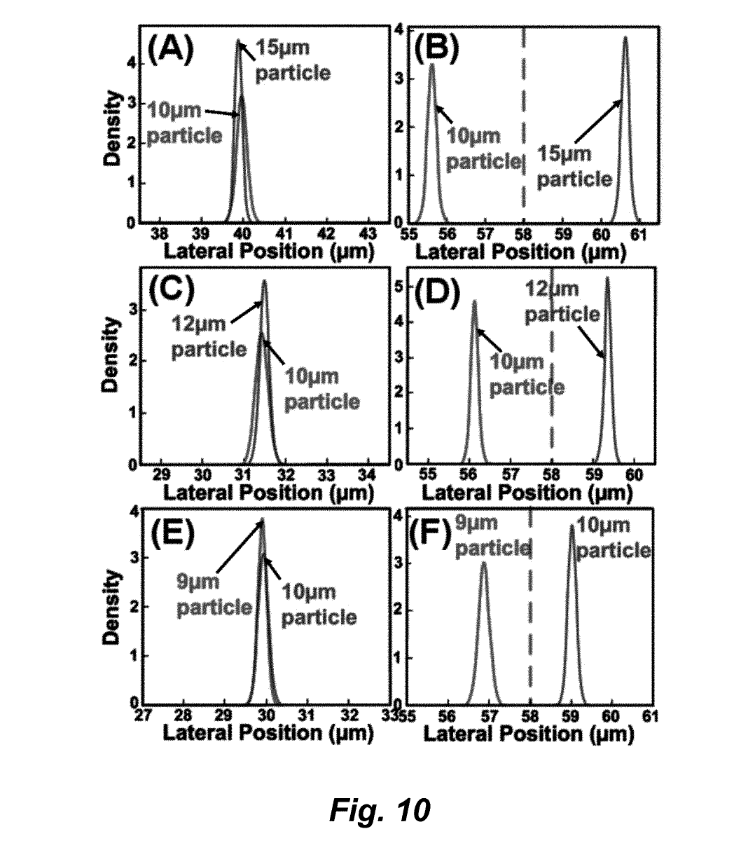

The histograms of particle positions at locations in FIG. 7(ii) and FIG. 7(iii) for these three mixtures are shown in FIG. 10. The size-independent focusing in the upstream with less than 0.2 μm standard variation of all four sizes of particles is the key to high purity sorting of particles with only 1 μm difference in size. Due to the laminar flow nature in microfluidics, the flow rate ratio between the collection (larger particles) and the waste (smaller particles) channels is around 0.5. As a result, as long as the separation of different sizes of particles can completely fall on either side of the dashed lines in FIG. 10(b, d, f), size-based particle sorting can be achieved.

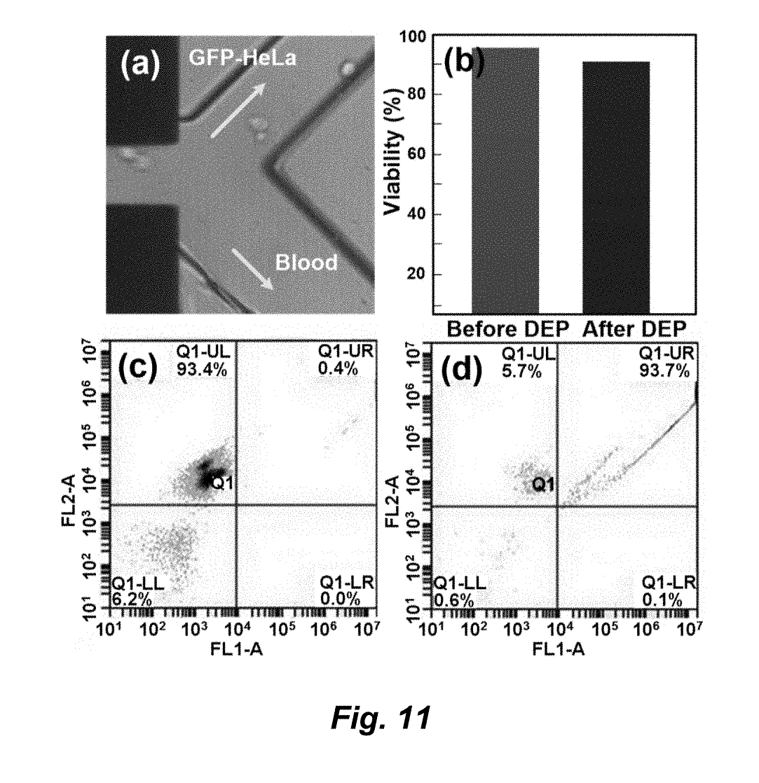

To demonstrate the bio-compatibility of this platform, we spiked rare GFP-HeLa cells into lysed human whole blood, and did the high purity size-based sorting. The regular sizes of GFP-HeLa cells and human white blood cells fall in the range of 15 μm˜20 μm and 8 μm˜12 μm, respectively. The sorting results are shown in FIG. 11. The original GFP-HeLa to white blood cell (WBC) purity is 0.4% (FIG. 5(c)) with 94% viability (FIG. 11(b)). After DEP sorting, the collection GFP-HeLa to WBC purity is 93.7% (FIG. 11(d)) with 92.1% viability (FIG. 11(b)), which corresponds to a 234 fold enrichment.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

1. A device for focusing cells, viruses, particles, molecules or molecular complexes in a microfluidic channel, said device comprising:
a microfluidic channel comprising a plurality of electrodes disposed on surfaces of said channel to provide three-dimensional spatially tunable tunnel electric field minimum for dielectrophoretic (DEP) forces that are perpendicular to hydrodynamic flows along the channel; and
a fluid within said channel providing said hydrodynamic flow along said channel;
wherein said device is configured to apply voltages to said electrodes to provide an spatially adjustable electric field minimum or electric field pattern that is programmable by the voltage combinations on each electrodes.

2. The device of claim 1, wherein said device comprises:
a microfluidic channel comprising a plurality of electrodes disposed to provide dielectrophoretic (DEP) forces that are perpendicular to hydrodynamic flows along the channel; and
wherein said device is configured to apply voltages to said electrodes to provide an electric field minimum that is not centered in said microfluidic channel.

3. The device of claim 1, wherein said device is configured to apply voltages independently to each of said electrodes.

4. The device of claim 1, wherein:
said device comprises two pairs of electrodes disposed parallel to each other around the microfluidic channel; and/or
said plurality of electrodes comprises electrodes disposed along each side of said microfluidic channel at or near the top of said channel and electrodes disposed along each side of said microfluidic channel at or near the bottom of said channel; or
said plurality of electrodes comprises electrodes disposed along the midline of each side of said microfluidic channel and along the midline of the top and bottom of said channel.

5-7. (canceled)

8. The device of claim 1, wherein said device applies an ac voltage to said electrodes, and
said ac voltage applied to said electrodes is independently at a frequency ranging from about 0 Hz, or from about 1 Hz, or from about 100 Hz, or from about 1 kHz, or from about 10 kHz, or from about 50 kHz, or from about 100 kHz, or from about 500 kHz, up to about 5 MHz, or up to about 10 MHz, or up to about 15 MHz, or up to about 20 MHz, or up to about 50 MHz, or up to about 100 MHz, or up to about 500 MHz, or ranging from about 10 kHz, or from about 50 kHz, or from about 100 kHz, or from about 500 kHz, up to about 5 MHz, or up to about 10 MHz, or up to about 15 MHz, or up to about 20 MHz; and/or
said voltage applied to said electrodes independently ranges from about close to 0V, or from about 0.001 mV, or from about 0.01 mV, or from about 0.1 mV, or from about 1 mV, or from about 100 mV, or from about 500 mV, or from about 1V, or from about 5V, or from about 10V, up to about 500V, or up to about 100V, or up to about 80V, or up to about 50V, or up to about 40V, or up to maximum voltage above which a fluid in said channel will undergo electrolysis, or ranges from about 1V, or from about 5V, or from about 10V, up to about 100V, or up to about 80V, or up to about 50V, or up to about 40V.

9. (canceled)

10. The device of claim 1, wherein:
said electrodes are configured to provide a field minimum at or near a lower or upper corner (diagonal region) of said channel; or
said electrodes are configured to provide a field minimum at or near one side of said channel and/or at or near the top or bottom of said channel.

11-12. (canceled)

13. The device of claim 1, wherein said channel is linear or serpentine.

14-15. (canceled)

16. The device of claim 1, wherein:
the average depth of said microfluidic channel ranges from about 0.1 μm, or from about 0.5 μm, or from about 1 μm, or from about 10 μm, or from about 20 μm, or from about 30 μm, up to about 100 μm, or up to about 80 μm, or up to about 60 μm, or up to about 50 μm, or up to about 40 μm; and/or
the average width of said microfluidic channel ranges from about 0.1 μm, or from about 0.5 μm, or from about 1 μm, or from about 10 μm, or from about 20 μm, or from about 30 μm, or from about 40 μm, or from about 50 μm, or from about 80 μm, or from about 100 μm up to about 500 μm, or up to about 400 μm, or up to about 300 μm, or up to about 200 μm, or up to about 400 μm, or up to about 500 μm, or up to about 1 mm.

17. (canceled)

18. The device of claim 1,
wherein said fluid has a conductivity that ranges from about 10⁻⁶ S/m, or from about 10⁻⁵ S/m, or from about 10⁻⁴ S/m, or from about 10⁻³ S/m, or from about 10⁻² S/m up to about 10 S/m, or up to about 5 S/m, or up to about 2 S/m, or up to about 1.5 S/m, or up to about 1 S/m.

19-26. (canceled)

27. A method of focusing cells, viruses, particles, molecules or molecular complexes to an off-center location in a microchannel, said method comprising:
introducing said cells, viruses, particles, molecules or molecular complexes into a device of claim 1, wherein said electrodes provide an electric field minimum that is not centered in said microfluidic channel; and
flowing said cells, viruses, particles, molecules or molecular complexes along a length of the channel sufficient to permit said cells, viruses, particles, molecules or molecular complexes to focus in said channel at an off-center location wherein said off-center location is the location of an electric field minimum.

28-37. (canceled)

38. A device for sorting cells, viruses, particles, molecules or molecular complexes, said device comprising:
a microfluidic channel comprising:
a first region comprising a first plurality of electrodes disposed to provide dielectrophoretic (DEP) forces that are perpendicular to hydrodynamic flows along the first region of said channel; and
a second region downstream from said first region comprising a second plurality of electrodes disposed to provide dielectrophoretic (DEP) forces that are perpendicular to hydrodynamic flows along the second region of said channel;
a fluid within said channel providing said hydrodynamic flow along said channel; and
wherein said device is configured to apply voltages to first plurality of electrodes to provide an electric field minimum at a first location in the cross-section of said channel and to apply voltages to said second plurality of electrodes to provide an electric field minimum at a second location in the cross-section of said channel, where said first location and said second location are different locations in the cross-section of said channel.

39. The device of claim 38, wherein:
said first location is at or near a wall of said channel and said second location is at or near the opposite wall of said channel; or
said first location is at or near a corner of said channel and said second location is diagonally opposite at or near a corner of said channel.

40. (canceled)

41. The device of claim 38, wherein the second region of said channel diverges into a plurality of channels whereby different size particle are diverted into different channels providing particle having different size or size distribution in each different channel of said plurality of channels.

42-43. (canceled)

44. The device of claim 38, wherein:
said device comprises a port or channel for introducing said cells, viruses, particles, molecules or molecular complexes into the first region of said channel; and/or
said device comprises a port or channel for introducing a sheath flow into said microfluidic channel.

45. (canceled)

46. The device of claim 38, wherein:
said first plurality of electrodes and said second plurality of electrodes independently each comprise two pairs of electrodes disposed parallel to each other around that region of the microfluidic channel; and/or
said first plurality of electrodes and said second plurality of electrodes each comprises electrodes disposed along each side of said microfluidic channel at or near the top of said channel and electrodes disposed along each side of said microfluidic channel at or near the bottom of said channel; or
said first plurality of electrodes and said second plurality of electrodes each comprises electrodes disposed along the midline of each side of said microfluidic channel and along the midline of the top and bottom of said channel.

47-49. (canceled)

50. The device of claim 38, wherein:
an ac voltage is applied to said first plurality of electrodes and to said second plurality of electrodes independently at a frequency from about 0 Hz, or from about 1 Hz, or from about 100 Hz, or from about 1 kHz, or from about 10 kHz, or from about 50 kHz, or from about 100 kHz, or from about 500 kHz, up to about 5 MHz, or up to about 10 MHz, or up to about 15 MHz, or up to about 20 MHz, or up to about 50 MHz, or up to about 100 MHz, or up to about 500 MHz, or ranging from about 10 kHz, or from about 50 kHz, or from about 100 kHz, or from about 500 kHz, up to about 5 MHz, or up to about 10 MHz, or up to about 15 MHz, or up to about 20 MHz; and/or
an ac voltage applied to said first plurality of electrodes and to said second plurality of electrodes independently ranges from about close to 0V, or from about 0.001 mV, or from about 0.01 mV, or from about 0.1 mV, or from about 1 mV, or from about 100 mV, or from about 500 mV, or from about 1V, or from about 5V, or from about 10V, up to about 500V, or up to about 100V, or up to about 80V, or up to about 50V, or up to about 40V, or up to maximum voltage above which a fluid in said channel will undergo electrolysis, or ranges from about 1V, or from about 5V, or from about 10V, up to about 100V, or up to about 80V, or up to about 50V, or up to about 40V.

51.-58. (canceled)

59. The device of claim 38, wherein:
the average depth of said microfluidic channel ranges from about 0.1 μm, or from about 0.5 μm, or from about 1 μm, or from about 10 μm, or from about 20 μm, or from about 30 μm, up to about 100 μm, or up to about 80 μm, or up to about 60 μm, or up to about 50 μm, or up to about 40 μm; and/or
the average width of said microfluidic channel ranges from about 0.1 μm, or from about 0.5 μm, or from about 1 μm, or from about 10 μm, or from about 20 μm, or from about 30 μm, or from about 40 μm, or from about 50 μm, or from about 80 μm, or from about 100 μm up to about 500 μm, or up to about 400 μm, or up to about 300 μm, or up to about 200 μm, or up to about 400 μm, or up to about 500 μm, or up to about 1 mm; and/or
said fluid has a conductivity that ranges from about 10⁻⁶ S/m, or from about 10⁻⁵ S/m, or from about 10⁻⁴ S/m, or from about 10⁻³ S/m, or from about 10⁻² S/m up to about 10 S/m, or up to about 5 S/m, or up to about 2 S/m, or up to about 1.5 S/m, or up to about 1 S/m.

60-65. (canceled)

66. The device of claim 38, wherein said hydrodynamic flows are at a rate ranging up to about 10 m/s, or up to about 5 m/s, or up to about 1 m/s, or up to about 50 cm/s, or up to about 20 cm/s, or up to about 15 cm/s, or up to about 11 cm/s, or up to about 10 cm/s, or up to about 8 cm/s, or up to about 5 cm/s, or up to about 3 cm/s, or up to about 1 cm/s, or up to about 500 μm/s, or up to about 250 μm/s, or up to about 100 μm/s, or up to about 50 μm/s, or up to about 30 μm/s, or up to about 20 μm/s, or up to about 10 μm/s.

67-69. (canceled)

70. The device of claim 38, wherein said device can separate a 9 μm particle from a 10 μm particle.

71. The device of claim 70, wherein said device can separate a 9 μm particle from a 10 μm particle at a flow rate of 3 cm/s.

72. The device claim 38, wherein said first region provides a 3D tunable, size-independent, single-stream focusing having sub-micron precision.

73. The device of claim 72, wherein said focusing precision of said first region is less than about 0.2 μm.

74. The device claim 38, wherein said second region provides a 3D tunable, size-independent, single-stream focusing having sub-micron precision.

75. The device of claim 74, wherein said focusing precision of said second region is less than about 0.2 μm.

76. The device of claim 72, wherein said focusing precision is at a flow rate of about 3 cm/s.

77. The device of claim 38, wherein said device provides sorting purity of greater than about 90%, or greater than about 94%, or greater than about 98%, or greater than about 99%.

78. (canceled)

79. A method of sorting cells, viruses, particles, molecules or molecular complexes, said method comprising:
introducing said cells, viruses, particles, molecules or molecular complexes into a device of claim 38; and
capturing said cells, viruses, particles, molecules or molecular complexes from said device that have been sorted by size.
